(19) United States
(12) Patent Application Publication
(10) Pub. No.: US 2026/0271189 A1
(43) Pub. Date: Sep. 10, 2026

(54) CIRCUIT DEVICE

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Akira HARAGUCHI, Yokkaichi-shi, Mie (JP)

(73) Assignees: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(21) Appl. No.: 19/490,089

(22) PCT Filed: Jun. 7, 2023
(86) PCT No.: PCT/JP2023/021207

§ 371 Date: Dec. 4, 2025

(51) Int. Cl. H05K 1/11; H05K 1/02

(52) U.S. Cl. CPC H05K 1/116; H05K 1/0203; H05K 2201/10272

(57) ABSTRACT

Provided is a technology capable of improving the productivity of a connection body of a circuit board and a jumper busbar. A circuit device includes a circuit board, a jumper busbar, and a conductive piece. The circuit board includes a first surface provided with a land, a second surface opposite to the first surface, and a through hole extending from the first surface to the second surface in a part where the land is provided. The jumper busbar includes a main plate portion located on an outer side of the second surface, and a protrusion protruding from the main plate portion and inserted into the through hole. The conductive piece is mounted on the first surface to extend across an end surface of the protrusion and the land, and welded to each of the end surface of the protrusion and the land.

### CROSS-REFERENCE TO RELATED APPLICATIONS

This application is the U.S. national stage of PCT/JP2023/021207 filed on Jun. 7, 2023, the content of which is incorporated herein.

### TECHNICAL FIELD

The present disclosure relates to a circuit device.

### BACKGROUND

JP 2010-62249A discloses a jumper busbar that is connected to a printed circuit board. The jumper busbar and the printed circuit board are connected by inserting connection terminals of the jumper busbar into through holes of the printed circuit board and performing flow soldering.

Typically, for larger current to be conducted through a jumper busbar, the plate thickness and plate width of the jumper busbar are increased, leading to an increase in the heat capacity of the jumper busbar. If such a jumper busbar having a large heat capacity is mounted by flow soldering, heat absorption during soldering increases, which may cause poor solder wicking (solder rising) and the like and affect productivity.

The present disclosure therefore has an object of providing a technology capable of improving the productivity of a connection body of a circuit board and a jumper busbar.

### SUMMARY

A circuit device according to the present disclosure includes: a circuit board; a jumper busbar; and a conductive piece, wherein the circuit board includes a first surface provided with a land, a second surface opposite to the first surface, and a through hole extending from the first surface to the second surface in a part where the land is provided, the jumper busbar includes a main plate portion located on an outer side of the second surface, and a protrusion protruding from the main plate portion and inserted into the through hole, and the conductive piece is mounted on the first surface to extend across an end surface of the protrusion and the land, and welded to each of the end surface of the protrusion and the land.

### Advantageous Effects

According to the present disclosure, it is possible to improve the productivity of a connection body of a circuit board and a jumper busbar.

### BRIEF DESCRIPTION OF DRAWINGS

FIG. 1 is a schematic perspective view showing a circuit device according to an embodiment.

FIG. 2 is a schematic perspective view showing the circuit device with an upper case removed.

FIG. 3 is a schematic plan view showing the circuit device with the upper case removed.

FIG. 4 is a schematic exploded perspective view showing the circuit device.

FIG. 5 is a schematic exploded perspective view showing part of the configuration of the circuit device.

FIG. 6 is a schematic block diagram showing a principal configuration of a power supply system using the circuit device.

FIG. 7 is a schematic sectional view taken along line VII-VII in FIG. 3.

FIG. 8 is a schematic sectional view taken along line VIII-VIII in FIG. 3.

FIG. 9 is a schematic sectional view taken along line IX-IX in FIG. 3.

FIG. 10 is a schematic sectional view taken along line X-X in FIG. 3.

FIG. 11 is a schematic sectional view taken along line XI-XI in FIG. 3.

FIG. 12 is a schematic sectional view taken along line XII-XII in FIG. 3.

FIG. 13 is a schematic perspective view for explaining an example of a manufacturing method for the circuit device.

FIG. 14 is a schematic perspective view for explaining an example of a manufacturing method for the circuit device.

FIG. 15 is a schematic plan view for explaining an example of a manufacturing method for the circuit device.

FIG. 16 is a schematic bottom view for explaining an example of a manufacturing method for the circuit device.

FIG. 17 is a schematic perspective view for explaining an example of a manufacturing method for the circuit device.

FIG. 18 is a schematic perspective view for explaining an example of a manufacturing method for the circuit device.

FIG. 19 is a schematic perspective view for explaining an example of a manufacturing method for the circuit device.

FIG. 20 is a schematic perspective view for explaining an example of a manufacturing method for the circuit device.

FIG. 21 is a schematic plan view for explaining an example of a manufacturing method for the circuit device.

FIG. 22 is a schematic sectional view taken along line XXII-XXII in FIG. 21.

FIG. 23 is a schematic perspective view for explaining an example of a manufacturing method for the circuit device.

FIG. 24 is a schematic perspective view for explaining an example of a manufacturing method for the circuit device.

### DETAILED DESCRIPTION OF PREFERRED EMBODIMENTS

First, embodiments of the present disclosure will be listed and described.

A circuit device according to the present disclosure is as follows.

In a first aspect, a circuit device includes: a circuit board; a jumper busbar; and a conductive piece, wherein the circuit board includes a first surface provided with a land, a second surface opposite to the first surface, and a through hole extending from the first surface to the second surface in a part where the land is provided, the jumper busbar includes a main plate portion located on an outer side of the second surface, and a protrusion protruding from the main plate portion and inserted into the through hole, and the conductive piece is mounted on the first surface to extend across an end surface of the protrusion and the land, and welded to each of the end surface of the protrusion and the land.

In the circuit device according to the first aspect, the jumper busbar and the circuit board are connected via the conductive piece welded to each of them. With welded connection, high energy can be concentratedly applied to a relatively narrow region including the connection part of the material, and therefore the influence of the heat capacity of the material on productivity can be reduced as compared with flow solder connection. Accordingly, even if the jumper busbar has a large heat capacity, the jumper busbar and the circuit board can be connected via the conductive piece in a relatively short time, and the productivity of the connection body of the jumper busbar and the circuit board can be improved.

In a second aspect, in the circuit device according to the first aspect, the main plate portion may have a main surface parallel to the second surface, and the protrusion may protrude from the main surface of the main plate portion. With this configuration, the circuit device can be reduced in thickness in a direction perpendicular to the second surface as compared with the case where the main surface of the main plate portion is perpendicular to the second surface.

In a third aspect, in the circuit device according to the first or the second aspect, the jumper busbar may be made of a metal primarily composed of aluminum. In this manner, the jumper busbar can be reduced in weight as compared with the case where the jumper busbar is made of a metal primarily composed of copper.

In a fourth aspect, in the circuit device according to the third aspect, each of the land and the conductive piece may be made of a metal primarily composed of copper. In this case, a first welded portion between the conductive piece and the jumper busbar is a dissimilar-metal joint between aluminum and copper, and a second welded portion between the conductive piece and the land is a similar-metal joint between copper. Even in such a case, with welded connection, it is easy to individually set welding conditions for the first welded portion and welding conditions for the second welded portion, so that a favorable welding state can be easily obtained in each of the first welded portion and the second welded portion.

In a fifth aspect, the circuit device according to any one of the first to the fourth aspects may further include a heat sink thermally connected to the jumper busbar. With this configuration, heat generated during current conduction through the jumper busbar is transferred to the heat sink. Accordingly, a significant increase in the temperature of the jumper busbar can be reduced even when a large current flows through the jumper busbar.

In a sixth aspect, the circuit device according to any one of the first to the fifth aspects may further include: an external connection busbar provided with a connection portion for connection with an external conductive member; and a molded resin portion obtained by insert molding with the external connection busbar as an insert component, and the molded resin portion may support a connection body of the circuit board and the jumper busbar. With this configuration, the connection body of the circuit board and the jumper busbar can be integrated with the external connection busbar via the molded resin portion.

In a seventh aspect, the circuit device according to the second aspect may further include: an external connection busbar provided with a connection portion for connection with an external conductive member; a molded resin portion obtained by insert molding with the external connection busbar as an insert component; an electronic component provided to extend across the external connection busbar and the circuit board; and a heat sink thermally connected to each of the jumper busbar and the external connection busbar, the molded resin portion may support a connection body of the circuit board and the jumper busbar so that the external connection busbar and the circuit board are adjacent to each other, the electronic component may include a first terminal portion connected to the external connection busbar and a second terminal portion connected to the land, and the heat sink may include a portion stacked with the jumper busbar and a portion stacked with the external connection busbar. With this configuration, the connection body of the circuit board and the jumper busbar can be integrated with the external connection busbar via the molded resin portion. As a result of the external connection busbar and the jumper busbar being connected via the electronic component, the circuit board, and the conductive piece, a large-current circuit is formed. Because the external connection busbar and the jumper busbar are thermally connected to the heat sink, heat generated during current conduction through such a large-current circuit is efficiently transferred to the heat sink. Accordingly, a significant increase in the temperature of the large-current circuit can be reduced even when a large current flows through the large-current circuit.

Specific examples of a circuit device according to the present disclosure will be described below with reference to the drawings. The present disclosure is not limited to these examples, but is defined by the claims and intended to include all modifications within the meaning and scope equivalent to the claims.

### Overview of Circuit Device

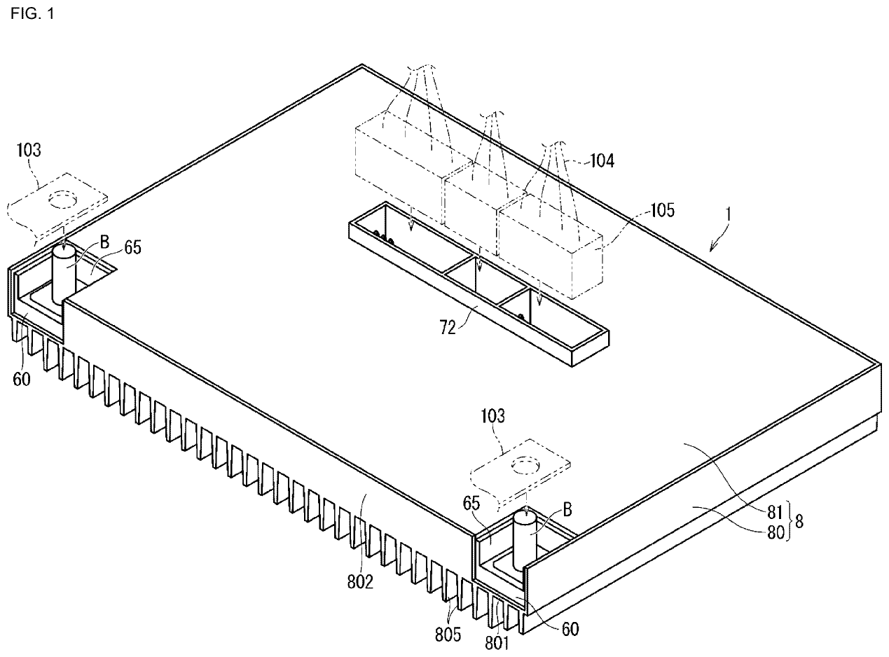

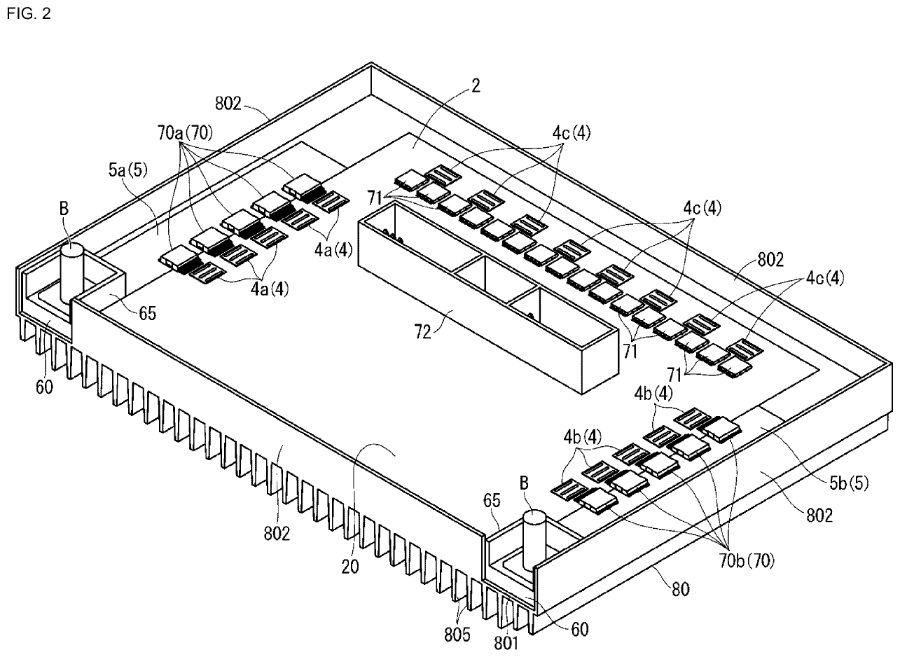

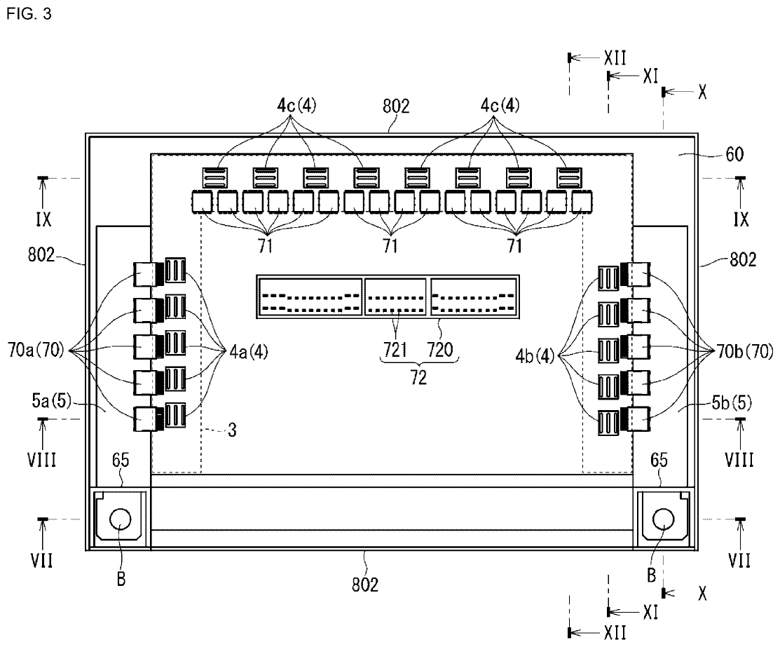

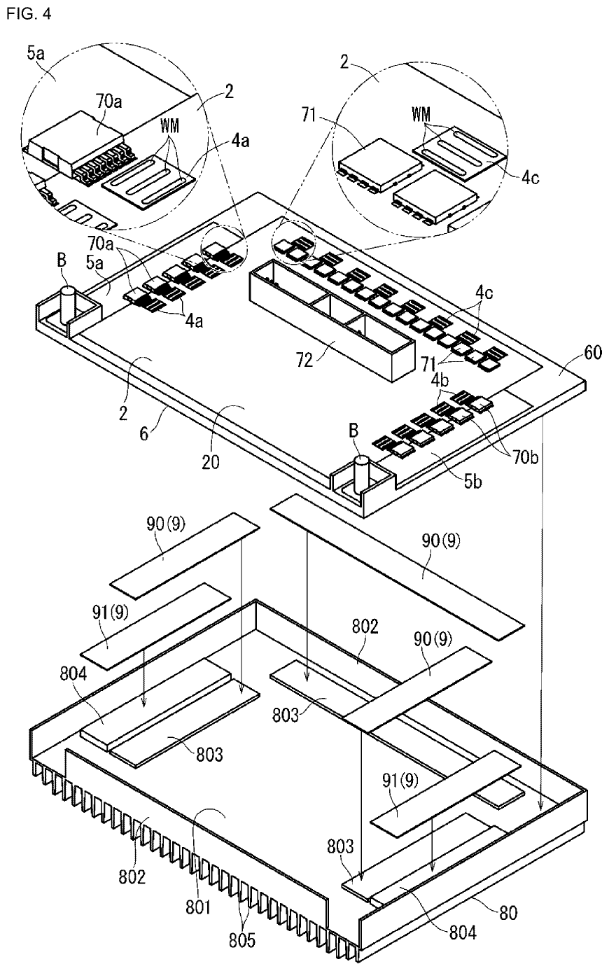

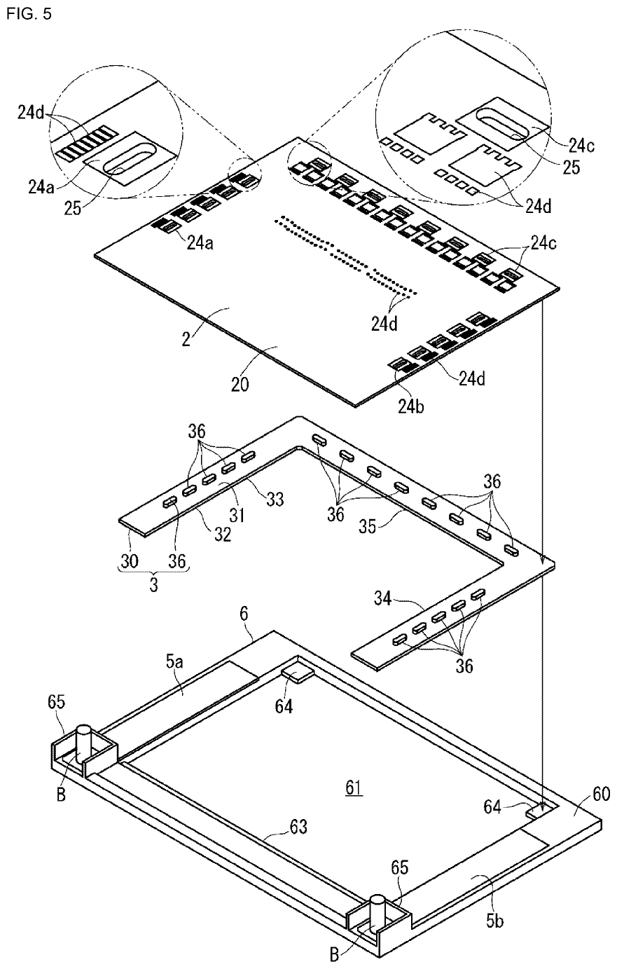

FIG. 1 is a schematic perspective view showing a circuit device 1 according to an embodiment. FIG. 2 is a schematic perspective view showing the circuit device 1 with an upper case 81 removed. FIG. 3 is a schematic plan view showing the circuit device 1 with the upper case 81 removed. FIG. 4 is a schematic exploded perspective view showing the circuit device 1. FIG. 5 is a schematic exploded perspective view showing part of the configuration of the circuit device 1. It is assumed herein that the side shown in FIG. 3 is the upper surface side or the upper side of the circuit device 1 and the opposite side is the lower surface side or the lower side of the circuit device 1, for convenience of explanation.

The circuit device 1 includes a circuit board 2, a jumper busbar 3, and a plurality of conductive pieces 4. The circuit device 1 also includes a pair of external connection busbars 5, a molded resin portion 6, a plurality of mounted components 7, a case 8, and a plurality of interposed members 9.

The circuit board 2 is, for example, a rectangular plate-shaped member. For example, the circuit board 2 includes an insulating substrate 22 and a conductive layer 23 provided on the insulating substrate 22. The insulating substrate 22 may be, for example, a ceramic substrate or a substrate containing resin. In the latter case, the insulating substrate 22 may be a glass epoxy substrate or another substrate containing resin. The conductive layer 23 may be formed of copper or formed of another metal. For example, the conductive layer 23 is provided on the upper surface of the insulating substrate 22. The circuit board 2 may be a single-layer substrate or a multilayer substrate. The circuit board 2 may have the conductive layer 23 not only on the upper surface but also on the lower surface, and may have the conductive layer 23 at an internal layer. In this embodiment, the circuit board 2 is a rigid board. Alternatively, the circuit board 2 may be a sheet-like flexible board, or a composite board in which a rigid board and a flexible board are integrated.

The circuit board 2 includes a first surface 20 and a second surface 21. A resist is provided on the first surface 20 to cover part of the conductive layer 23. Part of the conductive layer 23 not covered by the resist is exposed as a land 24. The circuit board 2 is provided with a plurality of lands 24. The circuit board 2 includes a plurality of through holes 25 extending from the first surface 20 to the second surface 21. The through holes 25 are formed in some of the plurality of lands 24.

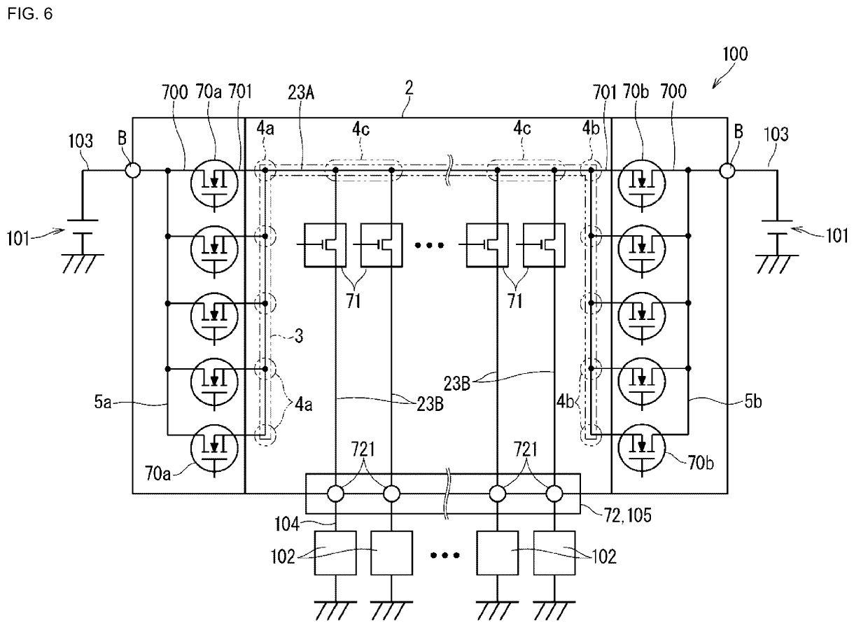

The plurality of lands 24 include a plurality of lands 24a, 24b, and 24c for connecting the conductive pieces 4, and a plurality of lands 24d for mounting the mounted components 7. The plurality of lands 24a, 24b, and 24c include a plurality of lands 24a arranged along one side of the four sides of the circuit board 2, a plurality of lands 24b arranged along another side, and a plurality of lands 24c arranged along still another side. The patterns of the plurality of lands 24a, 24b, and 24c are connected together in the part covered by the resist, thereby forming a main power supply circuit 23A (see FIG. 6 described later). A through hole 25 is formed in each of the lands 24a, 24b, and 24c. The patterns of some of the plurality of lands 24d are also connected to the pattern forming the main power supply circuit 23A.

The jumper busbar 3 is a metallic member. The jumper busbar 3 includes a main plate portion 30 with a flat plate shape, and a plurality of protrusions 36 protruding from the main plate portion 30. The main plate portion 30 includes a first extending portion 33, a second extending portion 34, and a third extending portion 35. The first extending portion 33 and the second extending portion 34 extend in parallel with each other while being spaced apart. The third extending portion 35 connects one end of the first extending portion 33 and one end of the second extending portion 34. The first extending portion 33, the second extending portion 34, and the third extending portion 35 in the main plate portion 30 form a recess. The plurality of protrusions 36 are arranged apart from each other in the extending direction of the main plate portion 30. The plurality of protrusions 36 include a plurality of protrusions 36 provided on the first extending portion 33, a plurality of protrusions 36 provided on the second extending portion 34, and a plurality of protrusions 36 provided on the third extending portion 35. The main plate portion 30 is located on the outside of the second surface 21 of the circuit board 2. The plurality of protrusions 36 protrude from the main plate portion 30 toward the circuit board 2 and are inserted into the plurality of through holes 25.

As shown in FIG. 5, the circuit board 2 and the main plate portion 30 of the jumper busbar are arranged in parallel. The main plate portion 30 has a first main surface 31 and a second main surface 32 opposite to the first main surface 31. For example, a pair of surfaces having the largest area from among the plurality of surfaces of the main plate portion 30 are the first main surface 31 and the second main surface 32 of the main plate portion 30. The first main surface 31 faces the second surface 21 of the circuit board 2. The plurality of protrusions 36 protrude from the first main surface 31 of the main plate portion 30. The circuit board 2 is provided on the first main surface 31 of the jumper busbar 3.

The plurality of conductive pieces 4 are provided at positions corresponding to the plurality of protrusions 36. Each conductive piece 4 is a metallic member larger than the through hole 25. The conductive piece 4 is disposed across (i.e. disposed so as to extend across) the peripheral edge of the through hole 25 of the land 24 and the end surface of the protrusion 36 inserted into the through hole 25. For example, the conductive piece 4 is disposed across the tip surface of the protrusion 36 and the land 24. The conductive piece 4 is welded to each of the land 24 and the end surface of the protrusion 36, and thus is fixed and electrically connected to each of the land 24 and the protrusion 36. The land 24 and the jumper busbar 3 are electrically connected via the conductive piece 4.

Each external connection busbar 5 is a metallic member. The external connection busbar 5 is, for example, a rectangular plate-shaped member. One end of the external connection busbar 5 is housed inside the case 8. The other end of the external connection busbar 5 is exposed outside the case 8. An external conductive member 103 is connected to the other end of the external connection busbar 5. Here, the other end of the external connection busbar 5 is provided with a bolt B in advance. The bolt B is used to connect the external connection busbar 5 and the external conductive member 103. Thus, the bolt B is an example of a connection portion of the external connection busbar 5 with the external conductive member 103.

The molded resin portion 6 electrically insulates the busbars 3 and 5 from each other while holding the busbars 3 and 5 and the circuit board 2 at fixed positions. For example, the molded resin portion 6 is integrally formed with the busbars 5 by insert molding in which the busbars 5 are used as insert components. The circuit board 2 and the busbar 3 are not used as insert components but are supported by the molded resin portion 6 after the molding of the molded resin portion 6. Hereinafter, a structure in which the circuit board 2 and the busbars are integrated by the molded resin portion 6 is also referred to as a board module.

The plurality of mounted components 7 include a plurality of electronic components 70, a plurality of electronic components 71, and a connector 72. The electronic components 70 and 71 are, for example, switching elements. The electronic components 70 and 71 may also be electronic components other than switching elements.

The electronic components are, for example, metal-oxide-semiconductor field-effect transistors (MOSFETs). A MOSFET is one type of semiconductor switching element. The electronic components 70 are hereinafter also referred to as MOSFETs 70. The electronic components 70 may also be switching elements other than MOSFETs. Each MOSFET 70 is disposed across (i.e. disposed so as to extend across) the circuit board 2 and the external connection busbar 5, and is surface-mounted by reflow soldering. The MOSFET 70 includes a drain terminal, a source terminal, and a gate terminal, for example. The drain terminal is connected to the external connection busbar 5, and the source terminal is connected to the circuit board 2.

The electronic components 71 are, for example, intelligent power devices (IPDs). An IPD is a chip in which a switching element, such as a MOSFET or an insulated gate bipolar transistor (IGBT), and a control circuit for controlling the switching element are integrated. The electronic components 71 are hereinafter also referred to as IPDs 71. The electronic components 71 may also be switching elements other than IPDs. Each IPD 71 is, for example, disposed on the circuit board 2 and surface-mounted by reflow soldering.

In this embodiment, the circuit device 1 includes ten MOSFETs 70 and sixteen IPDs 71. The number of MOSFETs 70 and the number of IPDs 71 included in the circuit device 1 are, however, not limited to such.

The connector 72 includes a housing 720 and a plurality of connector terminals 721. For example, the housing 720 is made of insulating resin, and the connector terminals 721 are made of metal. The housing 720 is provided on the first surface 20 of the circuit board 2. One end of each of the plurality of connector terminals 721 is held by the housing 720 in a state of being connectable to a connector terminal of a mating connector 105. Here, the housing 720 has an opening for receiving the mating connector 105, and one end of each of the plurality of connector terminals 721 is exposed within the opening. The other end of each of the plurality of connector terminals 721 is inserted into a through hole of the circuit board 2, and through hole mounted by flow soldering. When connecting the connector 72 and the mating connector 105, the housing 720 and a housing of the mating connector 105 are fitted together, and one end of each of the plurality of connector terminals 721 is connected to a corresponding connector terminal of the mating connector 105.

The case 8 covers the board module excluding the parts (connection portions) connected to the outside. The inside of the circuit device 1 is thus protected. The case 8 includes a lower case 80 and an upper case 81. The lower case 80 is formed in a box shape with an opening at the top. The board module is housed in the lower case 80. The upper case 81 is formed in a lid shape that closes the upper opening of the lower case 80. The bolt B and the opening portion of the connector 72 are exposed without being covered by the case 8.

In this embodiment, the lower case 80 serves as a heat sink 80. The heat sink 80 is, for example, a metallic member. The heat sink 80 is provided on the lower side of the board module. The heat sink 80 is thermally connected to the jumper busbar 3 and the external connection busbars 5. The heat sink 80 dissipates the heat generated by the busbars 3 and 5 and the heat generated by the MOSFETs 70 and IPDs 71 and transferred through the busbars 3 and 5, to the outside. The circuit device 1 including the case 8 can be regarded as an electric junction box.

The interposed members 9 include thermally conductive members 90 and 91. The thermally conductive members 90 are interposed between the heat sink 80 and the jumper busbar 3 to thermally connect the heat sink 80 and the jumper busbar 3. The thermally conductive members 90 are insulating members and may insulate the heat sink 80 from the jumper busbar 3. The thermally conductive members 91 are interposed between the heat sink 80 and the external connection busbars 5 to thermally connect the heat sink 80 and the external connection busbars 5. The thermally conductive members 91 are insulating members and may insulate the heat sink 80 from the external connection busbars 5.

The interposed members 9 includes a joining member 92 (see, for example, FIG. 8 described later). The joining member 92 is interposed between the circuit board 2 and the jumper busbar 3 to join the circuit board 2 and the jumper busbar 3. Specifically, the joining member 92 is interposed between the second surface 21 of the circuit board 2 and the first main surface 31 of the main plate portion 30 to join them. The joining member 92 is also interposed between the jumper busbar 3 and the molded resin portion 6 to join the jumper busbar 3 and the molded resin portion 6.

### Detailed Description of Circuit Device

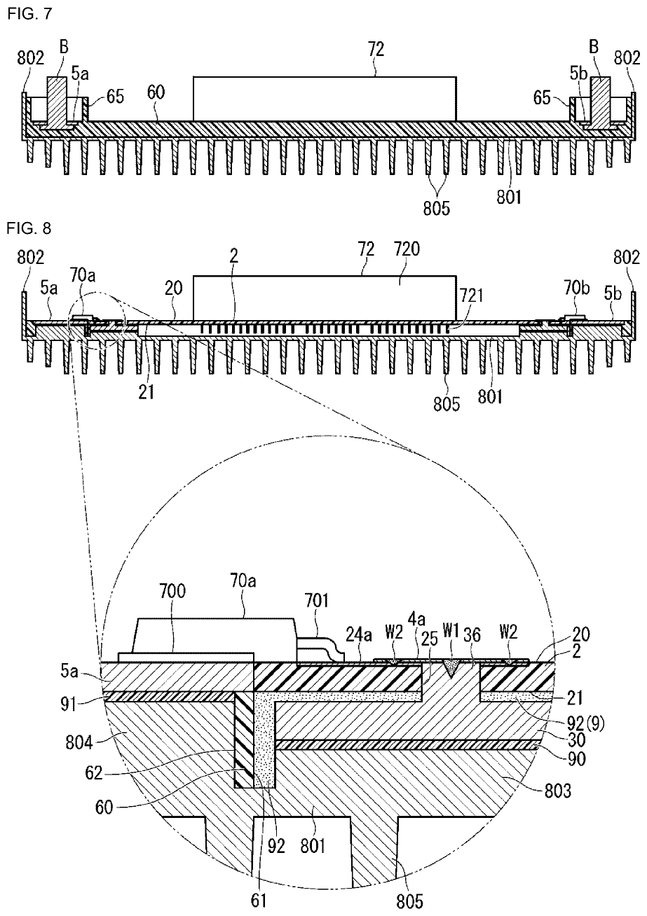

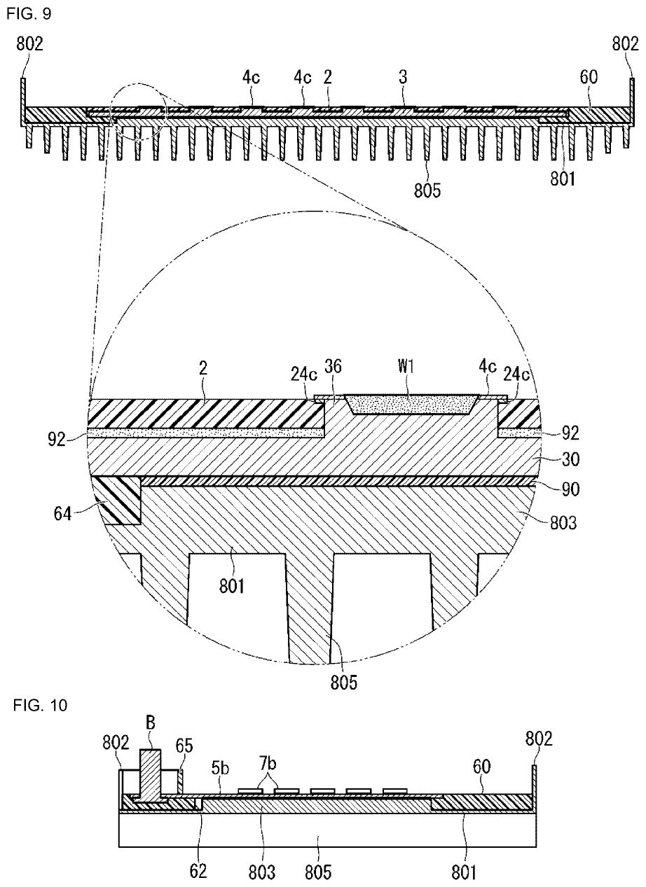

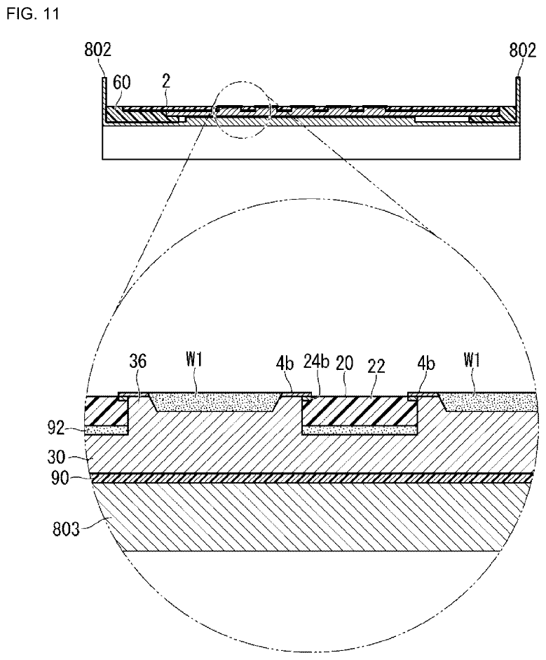

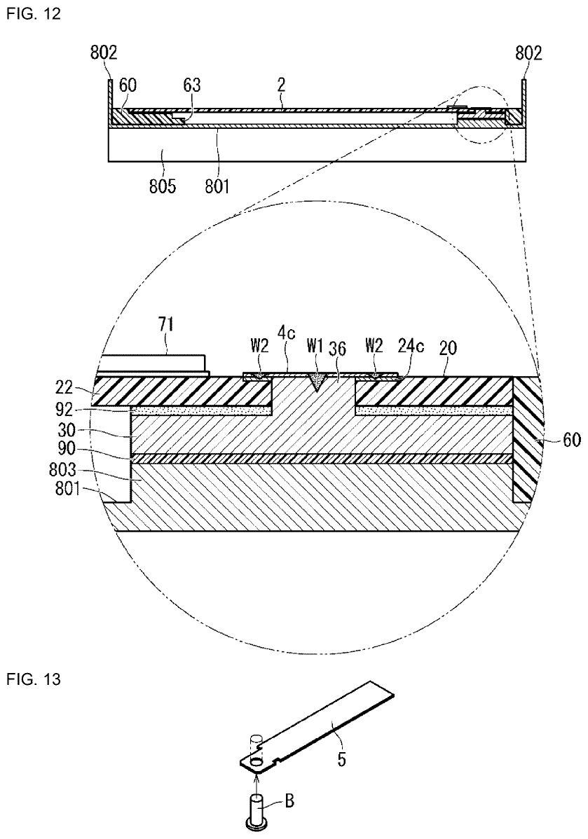

FIG. 6 is a schematic block diagram showing a principal configuration of a power supply system 100 using the circuit device 1. FIG. 7 is a schematic sectional view taken along line VII-VII in FIG. 3. FIG. 8 is a schematic sectional view taken along line VIII-VIII in FIG. 3. FIG. 9 is a schematic sectional view taken along line IX-IX in FIG. 3. FIG. 10 is a schematic sectional view taken along line X-X in FIG. 3. FIG. 11 is a schematic sectional view taken along line XI-XI in FIG. 3. FIG. 12 is a schematic sectional view taken along line XII-XII in FIG. 3.

### Power Supply System 100

As shown in FIG. 6, for example, the circuit device 1 is provided in the power supply system 100 of an automobile to form part of a power supply path between a battery 101 and various loads 102. The application of the circuit device 1 is not limited to such.

The conductive layer 23 of the circuit board 2 includes a main power supply circuit 23A, a plurality of load-side power supply circuits 23B, and a signal circuit (not shown). In the circuit device 1, each external connection busbar 5 and the main power supply circuit 23A are connected via the plurality of MOSFETs 70. In detail, the pair of external connection busbars 5a and 5b are electrically connected to the main power supply circuit 23A via MOSFETs 70a and 70b. The drain terminals 700 of the plurality of MOSFETs 70a are electrically connected to each other. The drain terminals 700 of the plurality of MOSFETs 70a are electrically connected to the external connection busbar 5a. The drain terminals 700 of the plurality of MOSFETs 70b are electrically connected to each other. The drain terminals 700 of the plurality of MOSFETs 70b are electrically connected to the external connection busbar 5b. The source terminals 701 of the plurality of MOSFETs 70a and 70b are electrically connected to each other. The source terminals 701 of the plurality of MOSFETs 70a and 70b are connected to the main power supply circuit 23A.

Moreover, the input terminals of the plurality of IPDs 71 are electrically connected to the main power supply circuit 23A. The input terminals of the plurality of IPDs 71 are electrically connected to each other. The output terminals of the plurality of IPDs 71 are not electrically connected to each other. The output terminals of the plurality of IPDs 71 are each connected to a corresponding one of the plurality of load-side power supply circuits 23B. The output terminals of the IPDs 71 are electrically connected to the connector terminals 721 through the load-side power supply circuits 23B.

The gate terminals of the MOSFETs 70 are electrically connected to the signal circuit of the circuit board 2. The control terminals of the IPDs 71 are electrically connected to the signal circuit of the circuit board 2. The MOSFETs 70 and the IPDs 71 are connected to a drive circuit via the signal circuit. The drive circuit may be provided in the circuit board 2, or provided in an electronic control unit (ECU) or the like outside the circuit device 1. The gate terminals of the MOSFETs 70 and the control terminals of the IPDs 71 may also be electrically connected to the connector terminals 721 through the signal circuit of the circuit board 2. The MOSFETs 70 and the IPDs 71 may be switching-controlled from the outside through the connector 72.

Each external connection busbar 5 is electrically connected to an external conductive member 103. The external conductive member 103 electrically connects the battery 101 and the circuit device 1, for example. The connector 72 is electrically connected to the mating connector 105. The mating connector 105 is provided, for example, on a wire harness 104. The wire harness 104 electrically connects the corresponding load 102 and the circuit device 1, for example.

Accordingly, the output voltage of the battery 101 is supplied to each load 102 through the external conductive member 103, the external connection busbar 5, the MOSFETs 70, the main power supply circuit 23A, the IPDs 71, the load-side power supply circuit 23B, the connectors 72 and 105, and the wire harness 104. The circuit device 1 is capable of switching control of the main power supply circuit 23A through the MOSFETs 70. With this configuration, the circuit device 1 is capable of switching control of the plurality of loads 102 collectively through the MOSFETs 70. The circuit device 1 is also capable of switching control of the plurality of load-side power supply circuits 23B individually through the plurality of IPDs 71. Accordingly, the circuit device 1 is capable of switching control of the plurality of loads 102 individually through the plurality of IPDs 71.

Currents for the plurality of loads 102 may simultaneously flow through the main power supply circuit 23A. When the number of loads 102 is larger, the current of the main power supply circuit 23A is larger. The jumper busbar 3 is provided as an auxiliary circuit of the main power supply circuit 23A. The jumper busbar 3 is connected to the main power supply circuit 23A at both an upstream position and a downstream position. Here, the position upstream of the main power supply circuit 23A is a position corresponding to the MOSFETs 70, and the position downstream of the main power supply circuit 23A is a position corresponding to the IPDs 71. Accordingly, the jumper busbar 3 is connected to the main power supply circuit 23A at both the position corresponding to the MOSFETs 70 and the position corresponding to the IPDs 71.

The jumper busbar 3 and the main power supply circuit 23A are connected via the plurality of conductive pieces 4. The plurality of conductive pieces 4 include a plurality of conductive pieces 4a, a plurality of conductive pieces 4b, and a plurality of conductive pieces 4c. The plurality of conductive pieces 4a correspond to the plurality of MOSFETs 70a. The plurality of conductive pieces 4b correspond to the plurality of MOSFETs 70b. Each of the conductive pieces 4a and 4b electrically connects the circuit board 2 and the jumper busbar 3 in the vicinity of the corresponding MOSFET 70a or 70b. The plurality of conductive pieces 4c correspond to the plurality of IPDs 71. Each of the conductive pieces 4c electrically connects the conductive layer 23 of the circuit board 2 and the jumper busbar 3 in the vicinity of the corresponding IPD 71. For example, the number of conductive pieces 4a is the same as the number of MOSFETs 70a. For example, the number of conductive pieces 4b is the same as the number of MOSFETs 70b. For example, the number of conductive pieces 4c is the same as the number of IPDs 71.

### Details of Components in Circuit Device 1

Each of the through holes 25 and the protrusions 36 has an elongated shape in one direction in plan view. The longitudinal direction of the protrusion 36 is parallel to the extending direction of the main plate portion 30. The conductive piece 4 has a plate shape thinner than the circuit board 2 and the main plate portion 30. The conductive piece 4 is thicker than the land 24 of the circuit board 2. The end surface of the protrusion 36 is flat, and is flush with the land 24 at the peripheral edge of the through hole 25. The conductive piece 4 has a rectangular shape. The conductive piece 4 is welded to the protrusion 36 and also welded to the land 24 on both sides of the protrusion 36 in its short-side direction.

The welded portion between the conductive piece 4 and the protrusion 36 of the jumper busbar 3 is referred to as a first welded portion W1, and the welded portion between the conductive piece 4 and the land 24 is referred to as a second welded portion W2. For one conductive piece 4, one first welded portion W1 and two second welded portions W2 are provided. The two second welded portions W2 are located on both sides of the one first welded portion W1.

For example, the first welded portion W1 and the second welded portion W2 are each a laser welded portion formed by a laser welder. In this case, for example, the conductive piece 4 is irradiated with laser light from the laser welder. The first welded portion W1 and the second welded portion W2 may each be a welded portion formed by a welding method other than laser welding. It is preferable that the first welded portion W1 and the second welded portion W2 are each formed by directly joining the welding materials without using a filler material.

The jumper busbar 3 is made of a metal primarily composed of aluminum. Each of the land 24 and the conductive piece 4 is made of a metal primarily composed of copper. Accordingly, the first welded portion W1 is a dissimilar-metal joint between the conductive piece 4 made of a metal primarily composed of copper and the protrusion 36 made of a metal primarily composed of aluminum, and the second welded portion W2 is a similar-metal joint between the conductive piece 4 made of a metal primarily composed of copper and the land 24 made of a metal primarily composed of copper. As mentioned above, one conductive piece 4 is provided with the first welded portion W1 which is a dissimilar-metal joint and the second welded portion W2 which is a similar-metal joint. Moreover, the first welded portion W1 is a joint between the thin conductive piece 4 and the protrusion 36 which is thicker than the conductive piece 4, and the second welded portion W2 is a joint between the thin conductive piece 4 and the land 24 which is thinner than the conductive piece 4. Even in such a case, when welding is used, it is easy to individually set welding conditions for the first welded portion W1 and welding conditions for the second welded portion W2, making it easy to set welding conditions suitable for each of the first welded portion W1 and the second welded portion W2.

For example, the penetration depth of the second welded portion W2 is shallower than the penetration depth of the first welded portion W1. By adjusting welding conditions (for example, the output of the welder) for welding of each welded portion, it is possible to adjust the penetration depth of the welded portion. Because the land 24 is provided on the first surface 20 of the circuit board 2, the land 24 is thinner than the protrusion 36 that passes through the circuit board 2. Because both the conductive piece 4 and the land 24 are primarily composed of copper, the conductive piece 4 and the land 24 can be favorably connected even with a shallow penetration depth. By making the penetration depth shallower, the thermal influence on the circuit board 2 during the welding of the second welded portion W2 can be reduced. Because the protrusion 36 is thicker than the land 24, it is easy to make the penetration depth deeper. By making the penetration depth of the first welded portion W1 deeper, welding can be reliably performed up to the interior part of the protrusion 36 made of aluminum. The penetration depth of the first welded portion W1 may be greater than the sum of the thickness dimensions of the land 24 and the conductive piece 4.

A weld mark WM may remain on the surface of the conductive piece 4. The weld mark WM is a part indicating the trace of welding of part of the conductive piece 4. The part of the conductive piece 4 where the weld mark WM is formed exhibits an appearance different from the appearance of the part of the conductive piece 4 that is not welded. The weld mark WM may be a part where the material of the conductive piece 4 and the material of the mating member (the protrusion 36 or the land 24), having been heated to a high temperature and melted together during welding, have appeared on the surface of the conductive piece 4. The weld mark WM may be formed in an elongated shape in the longitudinal direction of the protrusion 36. In one conductive piece 4, three weld marks WM may be provided so as to correspond to one first welded portion W1 and two second welded portions W2.

Among the plurality of lands 24d, the pattern of the land 24d connected to the source terminal 701 of the MOSFET 70 and the pattern of the land 24d connected to the input terminal of the IPD 71 are each connected to the pattern of a corresponding one of the lands 24a, 24b, and 24c forming the main power supply circuit 23A. The land 24d connected to the source terminal 701 of the MOSFET 70a and the land 24a may be not separate but form one land 24. The land 24d connected to the source terminal 701 of the MOSFET 70b and the land 24b may be not separate but form one land 24. The land 24d connected to the input terminal of the IPD 71 and the land 24c may be not separate but form one land 24. The lands 24a, 24b, and 24c may each have a projecting portion that extends outward beyond the outer edge of the conductive piece 4a, 4b, or 4c, and the source terminal 701 of the MOSFET 70 or the input terminal of the IPD 71 may also be connected to the projecting portion.

The rectangular circuit board 2 has a pair of first sides and a pair of second sides connecting the pair of first sides. The first extending portion 33 extends along one of the first sides of the circuit board 2, the second extending portion 34 extends along the other of the first sides, and the third extending portion 35 extends along one of the second sides. Here, the circuit board 2 is rectangular and has a pair of short sides and a pair of long sides. The first extending portion 33 extends along one of the short sides of the circuit board 2, the second extending portion 34 extends along the other of the short sides, and the third extending portion 35 extends along one of the long sides. The protrusions 36 are arranged apart from each other in the extending direction of each of the extending portions 33, 34, and 35.

The molded resin portion 6 supports the connection body of the circuit board 2 and the jumper busbar 3. The molded resin portion 6 includes a frame portion 60 that covers the periphery of the circuit board 2. An opening 61 is formed at the center of the frame portion 60, and the circuit board 2 is fitted into the opening 61. The opening 61 is formed in a rectangular shape having the same size as the circuit board 2. The molded resin portion 6 supports the connection body of the circuit board 2 and the jumper busbar 3 so that the external connection busbar 5 and the circuit board 2 are adjacent to each other.

The molded resin portion 6 includes support portions 63 and 64 that protrude from the inner side surface of the frame portion 60 toward the opening 61. The support portions 63 and 64 are provided so as to partially close the opening 61 at a position lower than the circuit board 2. One support portion 63 extends along the long side of the rectangular opening 61 so as to connect two corners. Two support portions 64 have a smaller rectangular shape than the support portion 63 and are provided at the remaining two corners of the rectangular opening 61. The jumper busbar 3 is supported on the upper surfaces of the support portions 63 and 64, and the circuit board 2 is supported on the upper surface of the jumper busbar 3. The upper surface (first surface 20) of the circuit board 2 supported by the support portions 63 and 64 and the main plate portion 30 of the jumper busbar 3 is flush with the upper surface of the frame portion 60. The thickness dimension of the frame portion 60 is approximately equal to the sum of the thickness dimension of the support portion 63 or 64, the thickness dimension of the jumper busbar 3, and the thickness dimension of the circuit board 2.

Each external connection busbar 5 is integrated with the frame portion 60. The upper surface of the frame portion 60 is flush with the upper surface of the external connection busbar 5. The upper surface of the external connection busbar 5 is exposed from the frame portion 60 without being covered by the frame portion 60. The circuit board 2 is supported by the molded resin portion 6 so that the first surface 20 of the circuit board 2 and the upper surface of the external connection busbar 5 are flush with each other. The molded resin portion 6 includes a wall portion 65 that is provided on the upper surface of the frame portion 60 and partition off the part of the external connection busbar 5 where the bolt B is provided. Part of the wall portion 65 also serves as a wall covering a sidewall of the upper case 81.

Part of the side surface of the external connection busbar 5 may also be exposed from the frame portion 60 and face the opening 61, without being covered by the frame portion 60. As shown in FIG. 8, part of the side surface of the circuit board 2 may also be in contact with the external connection busbar 5. Another part of the side surface of the circuit board 2 may also be in contact with the molded resin portion 6.

Part of the lower surface of the external connection busbar 5 may also be exposed from the frame portion 60 without being covered by the frame portion 60. An opening 62 for exposing part of the lower surface of the external connection busbar 5 may also be formed on the lower surface of the frame portion 60. As shown in FIG. 8, a wall may also be provided on the lower surface of the external connection busbar 5, the wall being part of the frame portion 60 and separating the opening 61 and the opening 62.

As shown in FIG. 8, the outer edge of the circuit board 2 may protrude outward beyond the outer edge of the jumper busbar 3. The side surface of the jumper busbar 3 may be spaced apart from the peripheral edge of the opening 61 of the frame portion 60. The side surface of the jumper busbar 3 may be joined to the inner side surface of the frame portion 60 via the joining member 92. The side surfaces of the first extending portion 33 and the second extending portion 34 of the jumper busbar 3 may be joined to the inner side surface of the frame portion 60 via the joining member 92. In the case where the external connection busbar 5 is thicker than the circuit board 2, the lower surface of the external connection busbar 5 protrudes downward beyond the lower surface of the circuit board 2. Even in such a case, the joining member 92 is interposed between the jumper busbar 3 and the external connection busbar 5. The joining member 92 is an insulating member that insulates the jumper busbar 3 from the external connection busbar 5. The side surface of the third extending portion 35 of the jumper busbar 3 is in contact with the frame portion 60, where the joining member 92 need not be provided.

The lower case 80, which also serves as the heat sink 80, includes a bottom plate portion 801, a side plate portion 802, connection protrusions 803 and 804, and fins 805. The side plate portion 802 and the connection protrusions 803 and 804 protrude from one surface side of the bottom plate portion 801, and the fins 805 protrude from the other surface side of the bottom plate portion 801. The side plate portion 802 extends along the outer edge of the bottom plate portion 801. The bottom plate portion 801 and the side plate portion 802 form a box portion that is open at the top and is used to house the board module. The bottom plate portion 801 supports the lower surface of the frame portion 60 of the board module.

The connection protrusions 803 and 804 are provided inward from the outer edge of the bottom plate portion 801. The connection protrusion 803 is provided at the part of the molded resin portion 6 where the opening 61 is located, and the connection protrusion 804 is provided at the part of the molded resin portion 6 where the opening 62 is located. The connection protrusion 803 is provided at a part corresponding to the part of the first extending portion 33, second extending portion 34, and third extending portion 35 not supported by the support portions 63 and 64. The connection protrusion 803 is inserted into the opening 61. The upper surface of the connection protrusion 803 is thermally connected to the lower surfaces of the first extending portion 33, second extending portion 34, and third extending portion 35 via a thermally conductive member 90. The connection protrusion 804 is provided at a part corresponding to the external connection busbar 5. The connection protrusion 804 is inserted into the opening 62. The upper surface of the connection protrusion 804 is thermally connected to the lower surface of the external connection busbar 5 via a thermally conductive member 91. The heat sink 80 includes the connection protrusion 803 as a portion stacked with the jumper busbar 3 and the connection protrusion 804 as a portion stacked with the external connection busbar 5.

As shown in FIG. 8, the connector terminals 721 are located at the center of the circuit board 2 surrounded by the main plate portion 30. The jumper busbar 3 and the connection protrusions 803 and 804 are not provided at the position of the connector terminals 721 in plan view. The tips of the connector terminals 721 are separated from the bottom plate portion 801. Thus, the connector terminals 721 are kept from being electrically connected to the jumper busbar 3 and the heat sink 80.

### Example of Manufacturing Method for Circuit Device 1

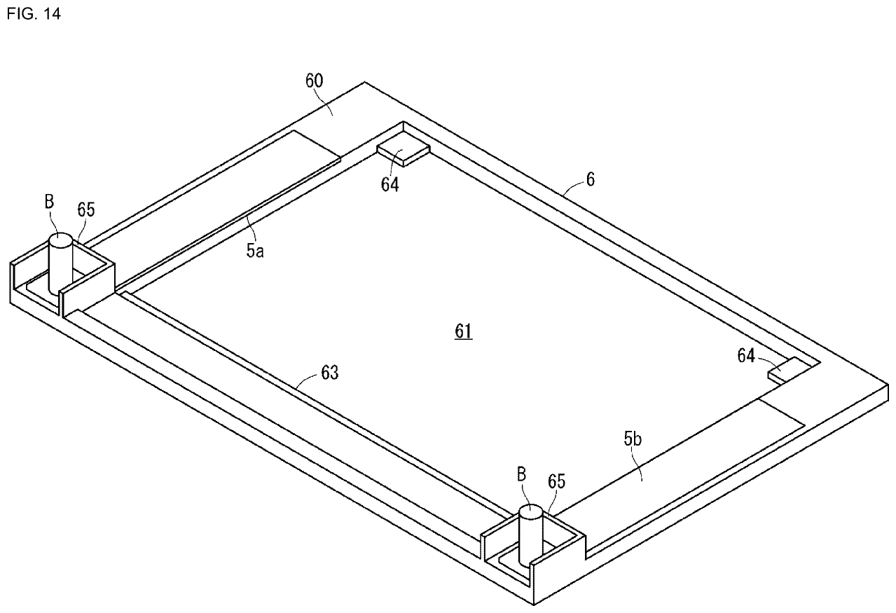

First, as shown in FIG. 13, a stud bolt B is press-fitted and fixed into a hole formed in each external connection busbar 5 that has been formed into a predetermined shape. The material of the external connection busbar 5 is, for example, oxygen-free copper (C1020) or a copper alloy, and its surface may be plated with nickel. The thickness of the external connection busbar 5 may be, for example, about 1.5 mm. The stud bolt B may be made of carbon steel for cold forging, for example.

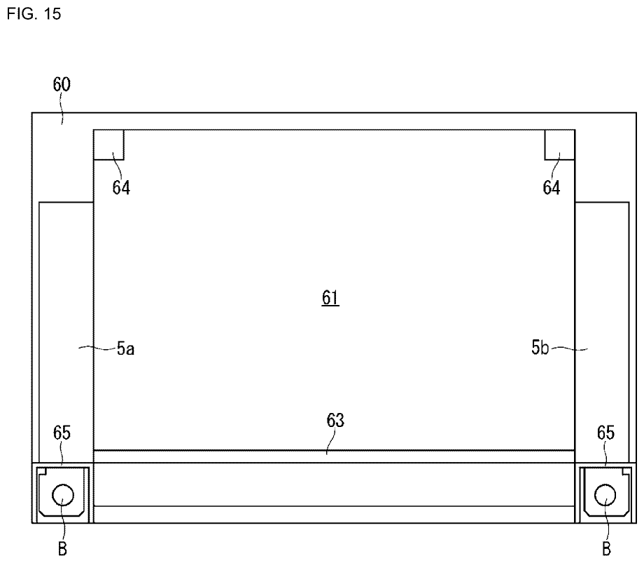

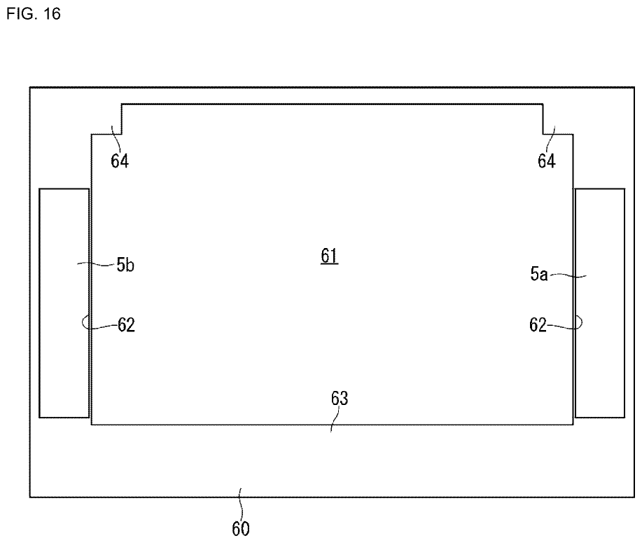

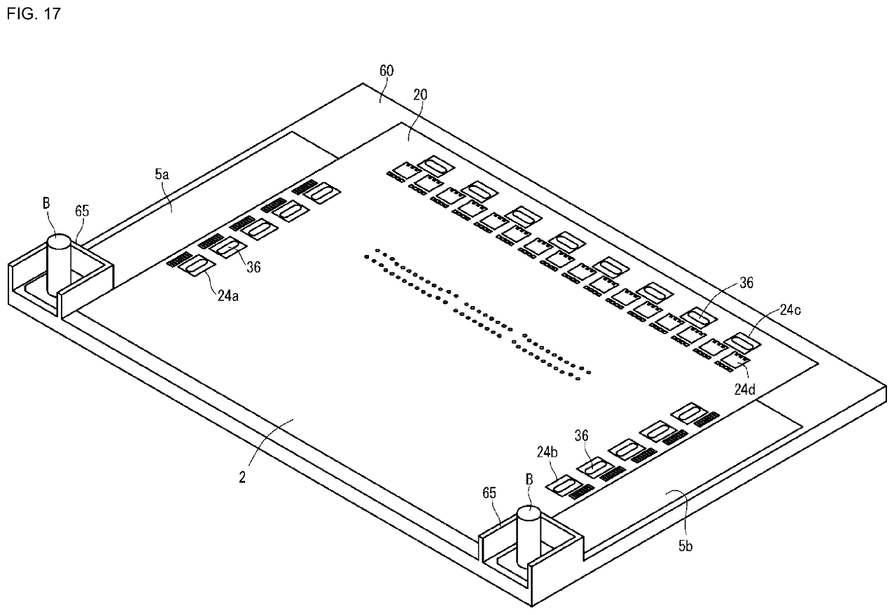

Next, the pair of external connection busbars 5 are arranged in an insert molding mold, and a resin material is injected into the mold by an injection molding machine. The resin material may be, for example, a thermoplastic resin with excellent heat resistance, such as PPS resin. As a result, the molded resin portion 6 is integrally molded with the external connection busbars 5, thereby producing a busbar insert substrate shown in FIGS. 14 to 16.

Next, as shown in FIG. 5, the busbar insert substrate, the circuit board 2, and the jumper busbar 3 are integrated. First, the protrusions 36 of the jumper busbar 3 are fitted into the through holes 25 formed in the lands 24 of the circuit board 2, and the circuit board 2 and the jumper busbar 3 are joined by the joining member 92. A connection body in which the jumper busbar 3 is attached to the circuit board 2 is thus formed. Here, the circuit board 2 and the jumper busbar 3 are positioned so that the surface of the protrusions 36 is flush with the lands 24. The connection body of the jumper busbar 3 and the circuit board 2 is then joined to the busbar insert substrate by the joining member 92. As a result, a board module shown in FIG. 17 is produced. The joining member 92 between the circuit board 2 and the jumper busbar 3 and the joining member 92 between the connection body and the busbar insert substrate may be a structure adhesive made of silicone, for example.

The circuit board 2 may be a copper-clad laminate in which copper foil is attached to the surface of the insulating substrate 22 made of glass epoxy resin. The thickness of the circuit board 2 may be, for example, from 1.2 mm to 1.6 mm. The thickness of the copper foil may be, for example, 70 μm.

The material of the jumper busbar 3 may be, for example, pure aluminum (A1050). The main plate portion 30 of the jumper busbar 3 results from forming a base material into a predetermined shape. The thickness of the main plate portion 30 may be, for example, about 2 mm. The protrusion amount of the protrusions 36 from the main plate portion 30 is equal to or slightly greater than the thickness dimension of the circuit board. The protrusions 36 of the jumper busbar 3 may be formed by bending deformation of part of the main plate portion 30 through dowel forming or the like. In this case, recesses corresponding to the protrusions 36 are formed in the parts of the second main surface 32 of the main plate portion 30 located on the back side of the protrusions 36. The protrusions 36 may be formed by removing part of the main plate portion 30 by etching or cutting. In this case, the entire second main surface 32 can remain flat as recesses corresponding to the protrusions 36 are not formed in the parts of the second main surface 32 of the main plate portion 30 located on the back side of the protrusions 36.

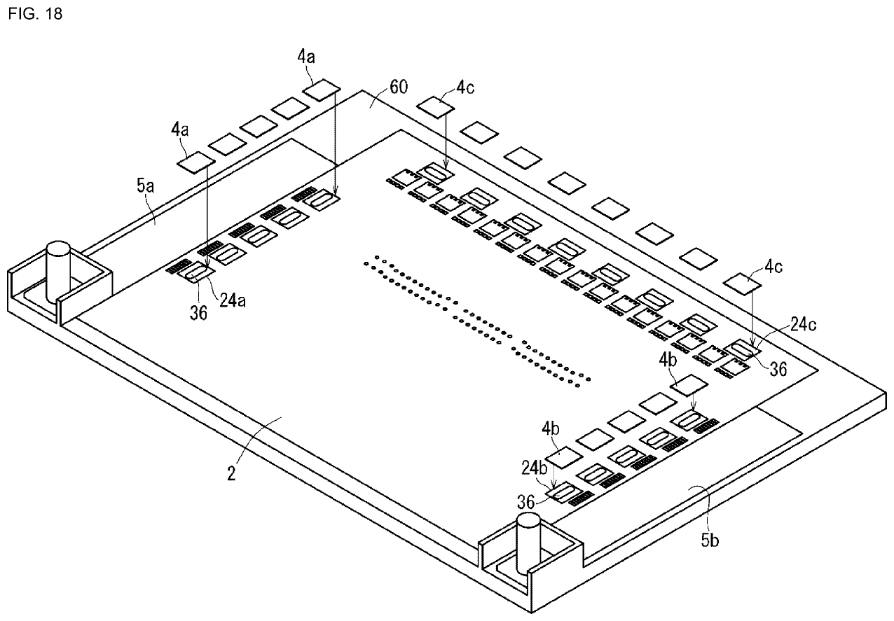

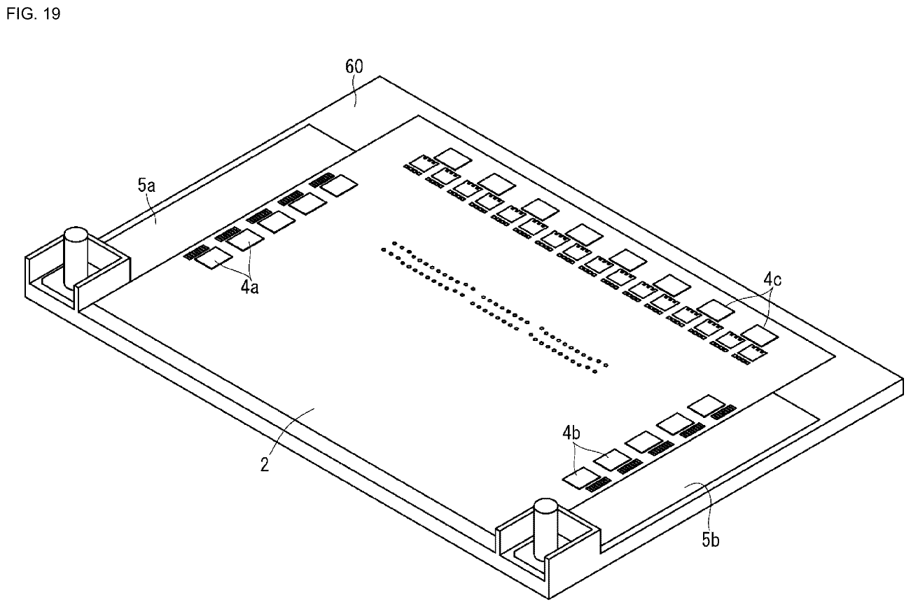

Next, as shown in FIGS. 18 and 19, each conductive piece 4 is placed so as to extend across the corresponding protrusion 36 and the land 24 adjacent to the protrusion 36. The material of the conductive piece 4 is, for example, pure copper or a copper alloy. The thickness of the conductive piece 4 is, for example, from 0.2 mm to 0.5 mm. The shape of the conductive piece 4 is, for example, a flat plate shape.

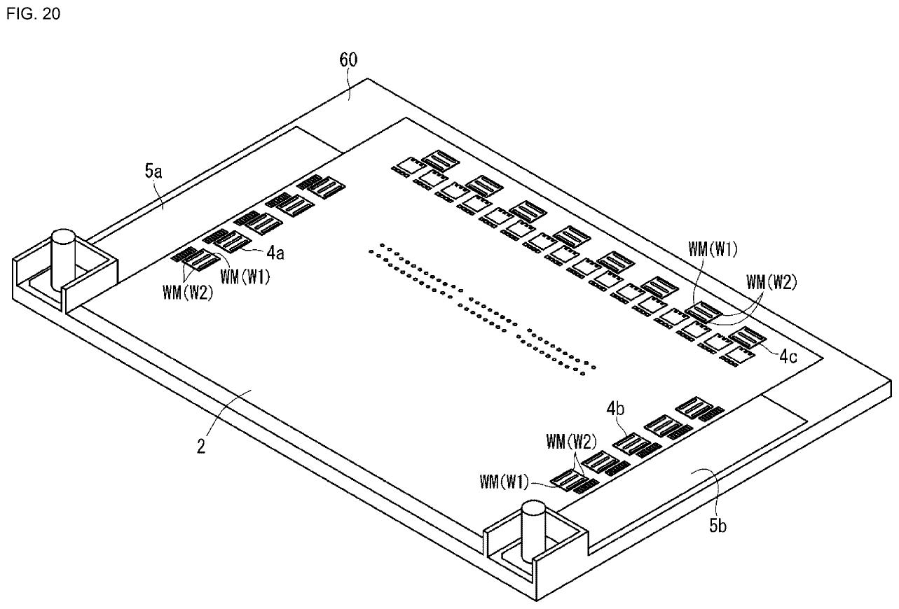

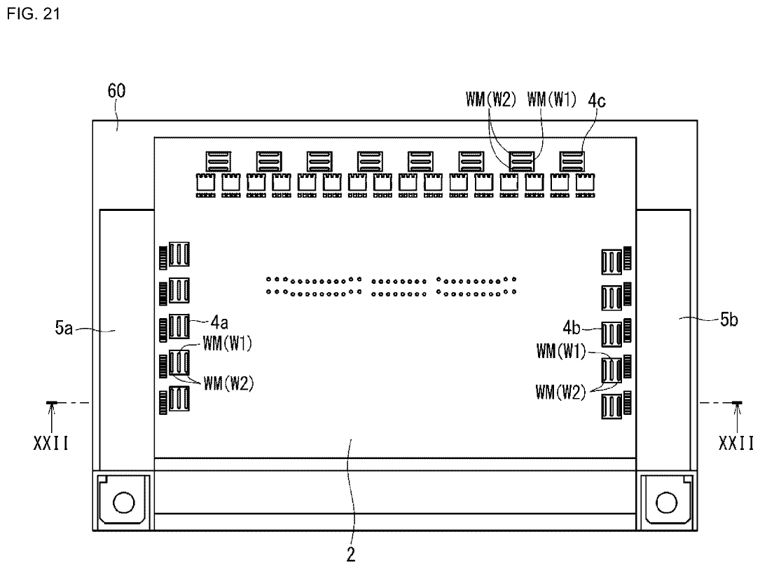

Next, as shown in FIGS. 20 and 21, the conductive piece 4 and the protrusion 36 are welded to form the first welded portion W1, and the conductive piece 4 and the land 24 are welded to form the second welded portion W2. The welder used here may be, for example, a laser welder. During welding of each of the first welded portion W1 and the second welded portion W2, the welding conditions of the welder may be optimized.

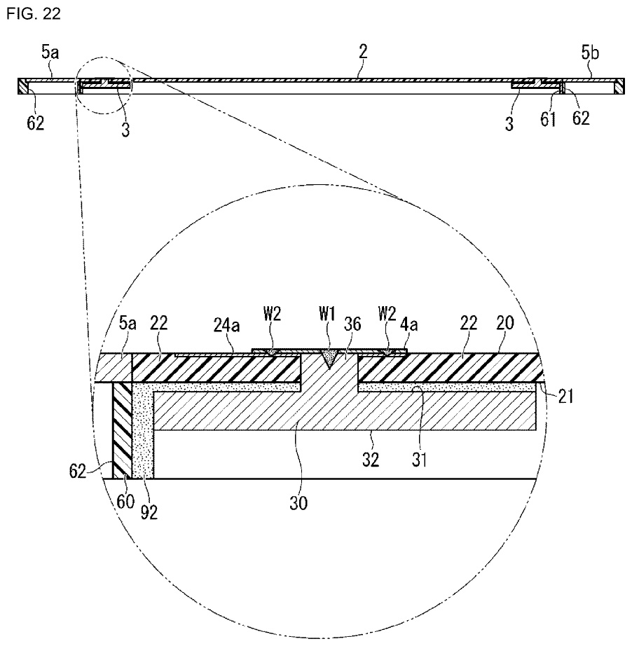

For example, the first welded portion W1 is a dissimilar-metal joint between a metal primarily composed of copper and a metal primarily composed of aluminum, whereas the second welded portion W2 is a similar-metal joint between metals primarily composed of copper. In addition, the land 24 and the protrusion 36 differ in thickness. The welding conditions of the welder may be set so that the penetration depth of the first welded portion W1 is deeper than the penetration depth of the second welded portion W2 as shown in FIG. 22. For example, the output of the laser welder during welding of the first welded portion W1 may be set higher than the output of the laser welder during welding of the second welded portion W2.

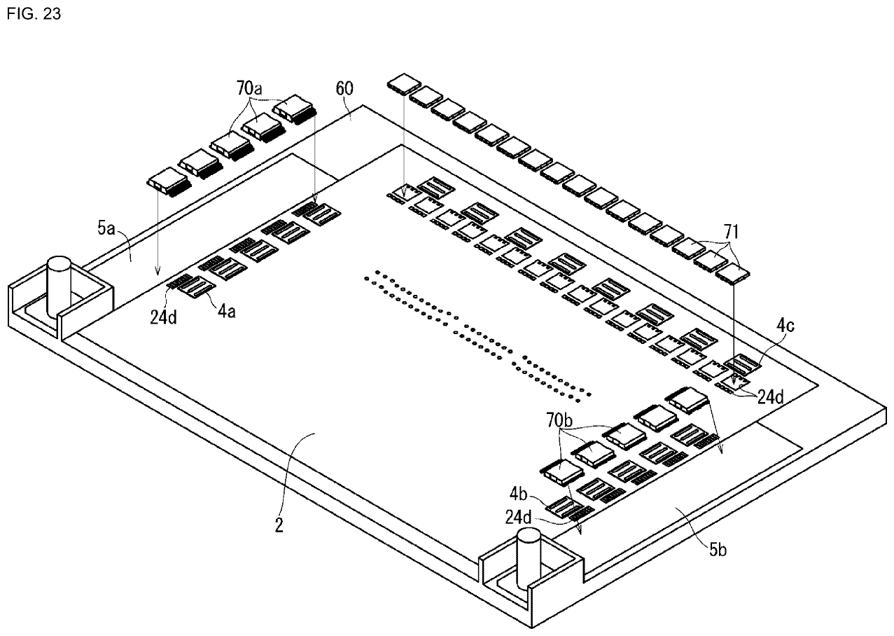

Next, a solder paste (not shown) is applied to a predetermined position on the board module. Then, as shown in FIG. 23, the MOSFETs 70 and the IPDs 71 are mounted and reflow soldered. At this time, other electronic components (not shown) may also be reflow soldered together.

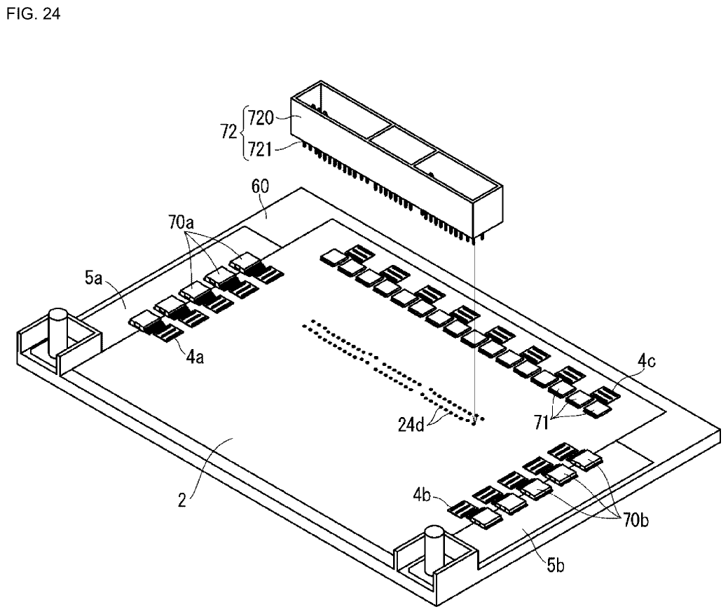

Next, as shown in FIG. 24, the connector terminals 721 of the connector 72 are mounted into through holes of the circuit board 2 and flow soldered.

Next, as shown in FIG. 4, the board module is mounted to the lower case 80 including the heat sink 80. As a result, the circuit device 1 with the upper case 81 removed as shown in FIG. 2 is produced. The lower case 80 and the board module may be fixed, for example, by screws (not shown). The lower case 80 is made of, for example, an aluminum die-cast material. The external connection busbars 5 and the jumper busbar 3 exposed on the back surface of the board module are thermally coupled to the lower case 80 via the thermally conductive members 90 and 91. The thermally conductive members 90 and 91 may be, for example, a heat dissipating sheet or heat dissipating grease. The thermally conductive members 90 and 91 thermally couple the lower case 80 and the external connection busbars 5 while insulating them. The thermally conductive members 90 and 91 thermally couple the lower case 80 and the jumper busbar 3 while insulating them.

Lastly, the upper case 81 is mounted. The circuit device 1 shown in FIG. 1 is thus manufactured.

### Effects

In the circuit device 1 configured as described above, the jumper busbar 3 and the circuit board 2 are connected via the conductive piece 4 welded to each of them. With welded connection, high energy can be concentratedly applied to a relatively narrow region including a connection part of the material, and therefore the influence of the heat capacity of the material on productivity can be reduced as compared with flow solder connection. Accordingly, even if the jumper busbar 3 has a large heat capacity, the jumper busbar 3 and the circuit board 2 can be connected via the conductive piece 4 in a relatively short time, and the productivity of the connection body of the jumper busbar 3 and the circuit board 2 can be improved.

Moreover, the main plate portion 30 has the first main surface 31 parallel to the second surface 21, and the protrusion 36 protrudes from the first main surface 31 of the main plate portion 30. With this configuration, the circuit device 1 can be reduced in thickness in a direction perpendicular to the second surface 21 as compared with the case where the first main surface 31 of the main plate portion 30 is perpendicular to the second surface 21.

Moreover, the jumper busbar 3 is made of a metal primarily composed of aluminum. Thus, the jumper busbar 3 can be reduced in weight as compared with the case where the jumper busbar 3 is made of a metal primarily composed of copper.

Moreover, each of the land 24 and the conductive piece 4 is made of a metal primarily composed of copper. In this case, the first welded portion W1 between the conductive piece 4 and the jumper busbar 3 is a dissimilar-metal joint between aluminum and copper, and the second welded portion W2 between the conductive piece 4 and the land 24 is a similar-metal joint between copper. Even in such a case, with welded connection, it is easy to individually set welding conditions for the first welded portion W1 and welding conditions for the second welded portion W2, so that a favorable welding state can be easily obtained in each of the first welded portion W1 and the second welded portion W2.

Moreover, the circuit device 1 includes a heat sink 80 thermally connected to the jumper busbar 3. Accordingly, heat generated during current conduction through the jumper busbar 3 is transferred to the heat sink 80. With this configuration, a significant increase in the temperature of the jumper busbar 3 can be prevented even when a large current flows through the jumper busbar 3.

Moreover, the circuit device 1 includes: an external connection busbar 5 provided with a connection portion for connection with an external conductive member 103; and a molded resin portion 6 obtained by insert molding with the external connection busbar 5 as an insert component, and the molded resin portion 6 supports a connection body of the circuit board 2 and the jumper busbar 3. Thus, the connection body of the circuit board 2 and the jumper busbar 3 can be integrated with the external connection busbar 5 via the molded resin portion 6.

As a result of the external connection busbar 5 and the jumper busbar 3 being electrically connected via the electronic components 70 and 71, the circuit board 2, and the conductive piece 4, a large-current circuit is formed. Because the external connection busbar 5 and the jumper busbar 3 are thermally connected to the heat sink 80, heat generated during current conduction through such a large-current circuit is efficiently transferred to the heat sink 80. Accordingly, a significant increase in the temperature of the large-current circuit can be prevented even when a large current flows through the large-current circuit.

### Supplementary Notes

In the foregoing examples, the power supply system 100 has redundancy because a plurality of loads 102 are connected to two batteries 101. In detail, even if power supply from one battery 101 to the loads 102 is interrupted, power can still be supplied from the other battery 101 to the loads 102. Alternatively, the plurality of loads 102 may also be connected to only one battery 101. In this case, one of the two sets of external connection busbars 5 and MOSFETs 70, i.e. the set of the external connection busbar 5a and the MOSFETs 70a and the set of the external connection busbar 5b and the MOSFETs 70b, may also be omitted in the circuit device 1. Further, in this case, the jumper busbar 3 may also be formed, for example, in an L-shape, with the connection portion to one set of an external connection busbar 5 and MOSFETs 70 omitted.

Although the case where the first main surface 31 of the main plate portion 30 is parallel to the second surface 21 of the circuit board 2 has been described above, this is not an essential configuration. The first main surface 31 of the main plate portion 30 may also be perpendicular to the second surface 21. In this case, the protrusion 36 may also protrude not from the first main surface 31 of the main plate portion 30 but from the side surface of the main plate portion 30.

Although the case where the jumper busbar 3 is made of a metal primarily composed of aluminum has been described above, this is not an essential configuration. The jumper busbar 3 may also be made of a metal primarily composed of copper.

Although the case where the circuit device 1 includes the molded resin portion 6 has been described above, this is not an essential configuration. For example, the circuit device 1 may also include, instead of the molded resin portion 6, a resin frame that is molded separately from the external connection busbar 5 and supports the circuit board 2, the jumper busbar 3, and the external connection busbar 5.

The configurations described in the above embodiments and modifications may be combined as appropriate as long as they are not mutually contradictory.

1. A circuit device comprising:
a circuit board;
a jumper busbar; and
a conductive piece,
wherein the circuit board includes a first surface provided with a land, a second surface opposite to the first surface, and a through hole extending from the first surface to the second surface in a part where the land is provided,
the jumper busbar includes a main plate portion located on an outer side of the second surface, and a protrusion protruding from the main plate portion and inserted into the through hole, and the conductive piece is mounted on the first surface to extend across an end surface of the protrusion and the land, and welded to each of the end surface of the protrusion and the land.

2. The circuit device according to claim 1, wherein the main plate portion has a main surface parallel to the second surface, and
the protrusion protrudes from the main surface of the main plate portion.

3. The circuit device according to claim 1,
wherein the jumper busbar is made of a metal primarily composed of aluminum.

4. The circuit device according to claim 3,
wherein each of the land and the conductive piece is made of a metal primarily composed of copper.

5. The circuit device according to claim 1, further comprising including;
a heat sink thermally connected to the jumper busbar.

6. The circuit device according to claim 1, further including;
an external connection busbar provided with a connection portion for connection with an external conductive member; and
a molded resin portion obtained by insert molding with the external connection busbar as an insert component,
wherein the molded resin portion supports a connection body of the circuit board and the jumper busbar.

7. The circuit device according to claim 2, further including;
an external connection busbar provided with a connection portion for connection with an external conductive member;
a molded resin portion obtained by insert molding with the external connection busbar as an insert component;
an electronic component provided to extend across the external connection busbar and the circuit board; and
a heat sink thermally connected to each of the jumper busbar and the external connection busbar,
wherein the molded resin portion supports a connection body of the circuit board and the jumper busbar so that the external connection busbar and the circuit board are adjacent to each other,
the electronic component includes a first terminal portion connected to the external connection busbar and a second terminal portion connected to the land, and
the heat sink includes a portion stacked with the jumper busbar and a portion stacked with the external connection busbar.
